(19) United States
(12) Patent Application Publication
(10) Pub. No.: US 2012/0098012 A1
(43) Pub. Date: Apr. 26, 2012

(54) ORGANIC LIGHT EMITTING DIODE DEVICE

(76) Inventors: Changoh KIM, Daejeon (KR); Hwakyung Kim, Gimpo-si (KR); Sunghoon Pieh, Seoul (KR); Kiwoog Song, Geumseong-ri (KR)

(21) Appl. No.: 13/278,831

(22) Filed: Oct. 21, 2011

(30) Foreign Application Priority Data
Oct. 21, 2010 (KR) 10-2010-0102923

(51) Int. Cl. H01L 33/44

(52) U.S. Cl. 257/98; 257/E33.061; 257/40

(57) ABSTRACT

An organic light emitting device is disclosed. An organic light emitting device according to one embodiment of the present invention comprises an anode; a first stack disposed on the anode and incorporating a first light emission layer comprising blue dopants for one host; a charge generation layer disposed on the first stack; a second stack disposed on the charge generation layer and incorporating blue and yellow dopants for one host or blue, red, and green dopants for one host; and a cathode disposed on the second stack.

This application claims the benefit of Korean Patent Application Nos. 10-2010-0102923 filed on October 21, which is hereby incorporated by reference in its entirety.

### BACKGROUND

1. Field

The present disclosure relates to an organic light emitting diode device. More specifically, the present disclosure relates to an organic light emitting diode device capable of improving luminous efficiency.

2. Related Art

Recently, flat panel displays (FPDs) are becoming more important with the widespread use of multimedia data. To meet the demand, various types of flat panel displays have been commercialized, including liquid crystal display (LCD), plasma display panel (PDP), field emission display (FED), organic light emitting device, and so on.

In particular, an organic light emitting device provides a high response speed, which is 1 ms or below, consumes low power and comprises a self-glowing material. The organic light emitting device has no limit on field of view. Accordingly, the organic light emitting device is attractive as a video display medium irrespective of the size of a device to be implemented. Also, since the organic light emitting device can be produced at low temperature and its related manufacturing process is simple employing a conventional semiconductor manufacturing process, the organic light emitting device is getting attention as a next generation flat panel display device.

An organic light emitting device comprises a light emission layer between an anode and a cathode. Holes provided from the anode and electrons from the cathode are combined in the light emission layer, thereby forming excitons, which are electron-hole pairs. The organic light emitting device emits light due to the energy generated as the excitons return to the ground state.

Organic light emitting devices are being developed in various types of structure. Among others, a white organic light emitting device has a structure such that a red, a green, and a blue light emission layer form a stack structure.

The white organic light emitting device of the stack structure has a problem due to a short life expectancy of the blue light emission layer and subsequent low color stability; and relatively high driving voltage. To solve the problem above, more layers are added, making the original structure more complex and inappropriate for mass production.

### SUMMARY

An organic light emitting device comprises an anode; a first stack disposed on the anode and incorporating a first light emission layer comprising blue dopants for one host; a charge generation layer disposed on the first stack; a second stack disposed on the charge generation layer and incorporating blue and yellow dopants for one host or blue, red, and green dopants for one host; and a cathode disposed on the second stack.

### BRIEF DESCRIPTION OF THE DRAWINGS

The accompany drawings, which are included to provide a further understanding of the invention and are incorporated on and constitute a part of this specification illustrate embodiments of the invention and together with the description serve to explain the principles of the invention.

FIG. 1 illustrates an organic light emitting device according to one embodiment of the present invention;

FIG. 2 is a simplified view of an organic light emitting device according to one embodiment of the present invention;

FIGS. 3a and 3b illustrate degree of reinforcement/cancellation of light according to the position of light emission layers of an organic light emitting device according to one embodiment of the present invention;

FIG. 4 illustrates a light emission spectrum of an organic light emitting device manufactured according to a comparative example 2 of the present invention; and

FIG. 5 illustrates a light emission spectrum of an organic light emitting device manufactured according to an experiment and a comparative example 1 of the present invention.

### DETAILED DESCRIPTION OF EXEMPLARY EMBODIMENTS

Reference will now be made in detail embodiments of the invention examples of which are illustrated in the accompanying drawings.

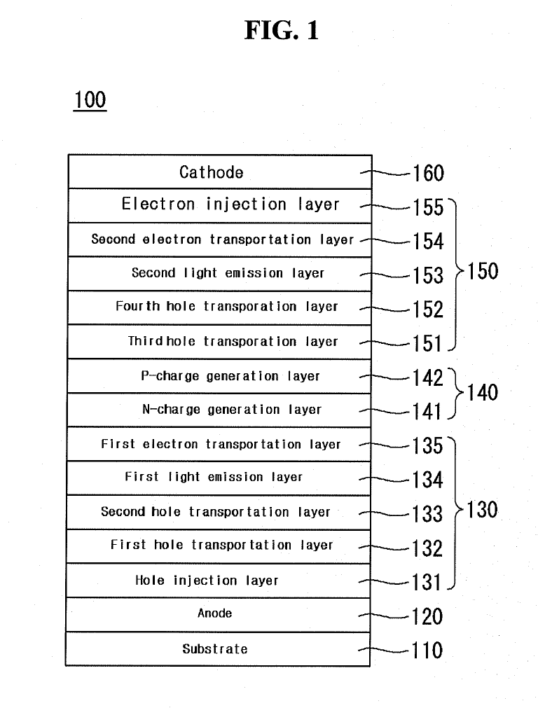

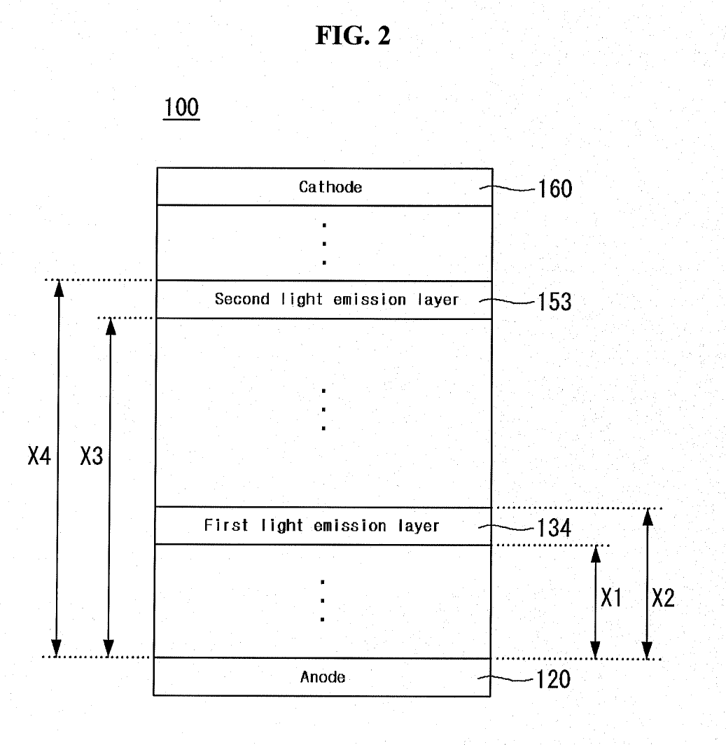

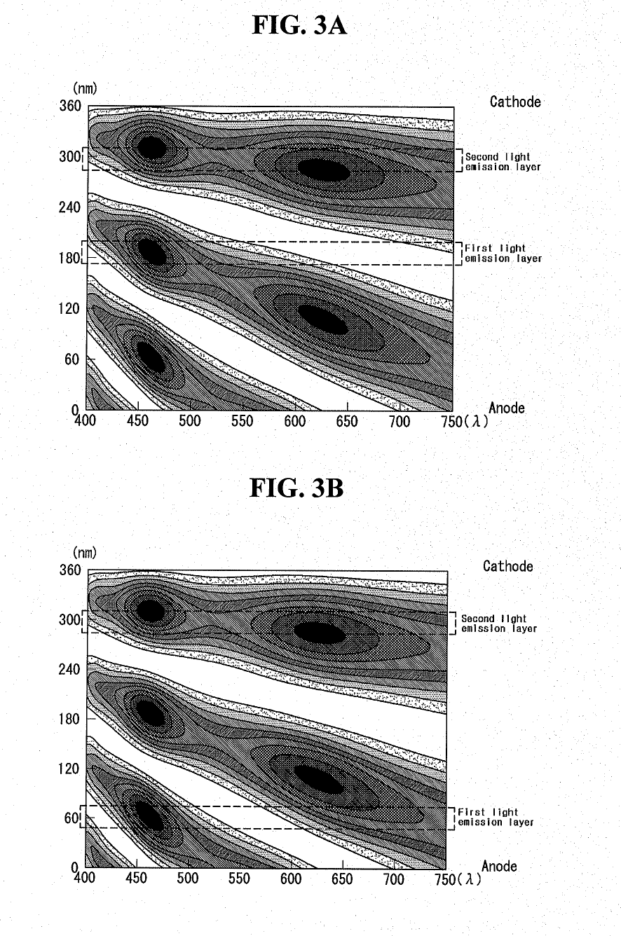

FIG. 1 illustrates an organic light emitting device according to one embodiment of the present invention; FIG. 2 is a simplified view of an organic light emitting device according to one embodiment of the present invention; and FIGS. 3a and 3b illustrate degree of reinforcement/cancellation of light according to the position of light emission layers of an organic light emitting device according to one embodiment of the present invention.

With reference to FIG. 1, an organic light emitting device 100 according to a first embodiment of the present invention can correspond to a white organic light emitting device including light of yellow and blue wavelength.

An organic light emitting device 100 according to one embodiment of the present invention comprises an anode 120 on a substrate 110, a first stack 130 incorporating a first light emission layer 134 disposed on the anode 120, a charge generation layer 140 disposed on the first stack 130, a second stack 150 incorporating a second light emission layer 153 disposed on the charge generation layer 140, and a cathode disposed on the second stack.

The substrate 110 can be made from transparent glass, plastic, or a conductive material.

The anode 120 can be a transparent or a reflective electrode. If the anode 120 is a transparent electrode, the anode 120 can be composed of ITO (Indium Tin Oxide), IZO (Indium Zinc Oxide), or ZnO (Zinc Oxide). Similarly, if the anode 120 is a reflective electrode, the anode can further comprise a reflection layer composed of Al, Ag, or Ni below the layer composed of ITO, IZO, or ZnO. Besides, the anode 120 can comprise the reflection layer between two layers composed of ITO, IZO, or ZnO.

The first stack 130 can comprise a first light emission layer 134 comprising fluorescent blue dopants for one host. The first stack 130 comprises only a blue light emission layer as the first light emission layer 134 and emits only blue rays, improving blue color stability.

The first light emission layer 134 emits blue rays; the first light emission layer 134 can be a mix of one host with fluorescent blue dopants.

As one example, the first light emission layer 134 can be a mix of a host material such as AND (9,10-di(2-naphthyl)anthracene) or DPVBi (4,4′-bis(2,2-diphenylethen-1-yl)-diphenyl) with fluorescent blue dopant such as 1,6-Bis(diphenylamine)pyrene or TBPe (tetrakis(t-butyl)perylene).

Also, the fluorescent blue dopant can be deep blue or sky blue dopant. Examples of the deep blue dopant include 4′-N,N-diphenylaminostyryl-triphenyl (DPA-TP); 2,5,2′,5′-2,5,2′,5′-tetrastyryl-biphenyl: TSB; anthracene derivatives; p-bis(p-N,N-diphenyl-aminostyryl)benzene; or phenylcyclopentadiene.

The first stack 130 can further comprise a hole injection layer 131 formed between the anode 120 and the first light emission layer 134; a first hole transportation layer 132; a second hole transfer layer 133; and a first electron transportation layer 135 formed between the first light emission layer 134 and the charge generation layer 140.

The hole injection layer 131 facilitates injection of holes to the first light emission layer 134 from the anode 120; and is composed of one or more selected from a group consisting of CuPc (copper phthalocyanine), PEDOT (poly(3,4)-ethylenedioxythiophene), PANI (polyaniline) and NPD (N,N-dinaphthyl-N,N′-diphenyl benzidine); but is not limited to the above.

The first hole transportation layer (HTL) 132 and the second hole transportation layer 133 facilitate transport of holes; and are composed of one or more selected from a group consisting of NPD (N,N-dinaphthyl-N,N′-diphenyl benzidine), TPD (N,N′-bis-(3-methylphenyl)-N,N′-bis-(phenyl)-benzidine), s-TAD and MTDATA (4,4′,4″-Tris(N-3-methylphenyl-N-phenyl-amino)-triphenylamine); but are not limited to the above.

The first electron transportation layer (ETL) 135 facilitates transport of electrons; and is composed of one or more selected from a group consisting of Alq3(tris(8-hydroxyquinolino)aluminum), PBD, TAZ, spiro-PBD, BAlq, and SAlq; but is not limited to the above.

The charge generation layer (CGL) 140 is composed of a double layer.

To be more specific, the charge generation layer 140 can be a PN junction charge generation layer joining N-type charge generation layer 141 and P-type charge generation layer 142. At this time, the PN junction charge generation layer 140 generates charges or separates them into holes and electrons; and injects the charges into the individual light emission layer. In other words, the N-type charge generation layer 141 provides electrons for the first light emission layer 134 adjacent to the anode while the P-type charge generation layer 142 provides holes to the second light emission layer 153 adjacent to the cathode 160, by which luminous efficiency of an organic light emitting device incorporating multiple light emission layers can be further improved and at the same time, driving voltage can be lowered.

The P-type charge generation layer 142 can be composed of metal or organic material doped with P-type dopant. Here, the metal can be one or an alloy consisting of two or more selected from a group consisting of Al, Cu, Fe, Pb, Zn, Au, Pt, W, In, Mo, Ni, and Ti. Also, P-type dopant and host used for organic material doped with the P-type can employ conventional materials. For example, the P-type dopant can be one selected from a group consisting of tetrafluore-7,7,8,8-tetracyanoquinodimethane (F4-TCNQ), derivative of tetracyanoquinodimethane, iodine, FeCl3, FeF3, and SbC15. Also, the host can be one selected from a group consisting of N,N′-di(naphthalen-1-yl)-N,N-diphenyl-benzidine (NPB), N,N′-diphenyl-N,N′-bis(3-methylphenyl)-1,1-biphenyl-4,4′-diamine (TPD) and N,N′,N′-tetranaphthyl-benzidine (TNB).

The N-type charge generation layer 141 can be composed of metal or organic material doped with N-type. At this time, the metal can be one selected from a group consisting of Li, Na, K, Rb, Cs, Mg, Ca, Sr, Ba, La, Ce, Sm, Eu, Tb, Dy, and Yb. Also, N-type dopant and host used for organic material doped with the N-type can employ conventional materials. For example, the N-type dopant can be alkali metal, alkali metal compound, alkali earth metal, or alkali earth metal compound. More specifically, the N-type dopant can be one selected from a group consisting of Cs, K, Rb, Mg, Na, Ca, Sr, Eu and Yb. The host material can be one selected from a group consisting of tris(8-hydroxyquinoline)aluminum, triazin, hydroxyquinoline derivative, benzazol derivative, and silole derivative.

The second stack 150 can comprise blue and yellow dopant for one host; or the second light emission layer 153 comprising blue, red, and green dopant for one host.

As one example, if the second light emission layer 153 comprises blue and yellow dopant for one host, the same material used for the host and blue dopant of the first light emission layer 134 can be employed as a host and blue dopant while Irpq2acac (bis(phenylquinoline) iridium acetylacetonate) is used as yellow phosphorescent dopant.

On the other hand, if the second light emission layer 153 comprises blue, red, and green dopant, Ir(piq)2acac (bis(phenyl isoquinoline) iridium acetylacetonate) can be employed as the red phosphorescent dopant for the host while Irppy3 (tris(phenyl pyridine) iridium) can be used as green phosphorescent dopant.

The second stack 150 can further comprise a third hole transportation layer 151 and a fourth hole transportation layer 152 formed between the charge generation layer 140 and the second light emission layer 153; and a second electron transportation layer 154 and an electron injection layer 155 formed between the second light emission layer 153 and the cathode 160.

Since the third hole transportation layer 151, the fourth hole transportation layer 152, and the second electron transportation layer 154 are the same as the first hole transportation layer 132 and the first electron transportation layer 135, related description will be omitted.

The electron injection layer (EIL) 155 facilitates injection of electrons and is composed of Alq3 (tris(8-hydroxyquinolino)aluminum), PBD, TAZ, Spiro-PBD, BAlq, or SAlq, but is not limited to the above. The electron injection layer 155 can further comprise alkali metal or metallic compound incorporating alkali earth metal.

The cathode 160 can be composed of aluminum (Al), magnesium (Mg), silver (Ag), or an alloy of the above. At this time, the cathode 160 can be formed to be so thin that light rays can pass through the cathode 160 in the case of front surface light emission. On the other hand, the cathode 160 can be formed to be thick such that light rays reflect in the case of rear surface light emission.

In an organic light emitting device composed as above according to one embodiment of the present invention, each light emission layer can be disposed as follows.

With reference to FIG. 2, the first light emission layer 134 of the present invention can be disposed being separated from the surface of the anode 120 by a first distance X1 and can be disposed at a position not going beyond a second distance X2. At this time, the first distance X1 can range from about 50 nm to about 175 nm while the second distance X2 from about 75 nm to about 200 nm.

In other words, the first light emission layer 134 of the present invention can be disposed within 50 to 75 nm or within about 175 to about 200 nm from the surface of the anode 120.

The second light emission layer 153 of the present invention can be disposed being separated from the surface of the anode 120 by a third distance X3 and can be disposed at a position not going beyond a fourth distance X4. At this time, the third distance X3 can be 285 nm while the fourth distance X4 310 nm.

In other words, the second light emission layer 153 of the present invention can be disposed within 285 to 310 nm from the surface of the anode 120.

As described above, with reference to FIGS. 3a and 3b illustrating degree of reinforcement/cancellation of light according to the position of the first 134 and the second light emission layer 153 of the present invention, the vertical axis denotes distance by which light emission layers are separated from the surface of the anode while the horizontal axis denotes wavelength of light.

The area where reinforcement of light is largest corresponds to the center region of a contour map. The farther from the center area, the weaker becomes the reinforcement of light and the area with the deepest color corresponds to where light is cancelled out.

First, with reference to FIG. 3a, the area where reinforcement of blue rays with a wavelength of 450 nm appears most corresponds to the area separated by about 180 nm and the area by about 310 nm from the surface of the anode. Also, as shown in FIG. 3b, the area where reinforcement of blue rays with a wavelength of 450 nm appears most corresponds to the area separated from the surface of the anode by about 60 nm.

Accordingly, by disposing the first light emission layer 134 within a range of about 50 to about 75 nm or about 175 to about 200 mm from the surface of the anode 120 and the second light emission layer 153 within a range of about 285 to about 310 nm from the surface of the anode 120, blue rays can reveal the maximum luminous efficiency.

As described above, an organic light emitting device according to one embodiment of the present invention emits blue rays at the first light emission layer; and further incorporates yellow dopant or blue dopant in addition to red and green dopant at the second light emission layer, improving luminous efficiency of blue rays.

Also, the present invention provides an advantage that blue rays can show the maximum luminous efficiency as the position of the first and the second light emission layer is adjusted.

In what follows, an experimental example according to one embodiment of the present invention is described. However, the experimental example described below is just one embodiment of the present invention but is not limited to the one below.

### Experimental Example

ITO glass is patterned in such a way that the size of a light emitting area amounts to 2 mm×2 mm and the patterned ITO glass is washed. The substrate is loaded into a vacuum chamber and a base pressure of 1×10-6 torr is applied to the chamber. A hole injection layer DNTPD is coated on the ITO corresponding to the anode with a thickness of 50□. The first hole transportation layer NPD is coated with a thickness of 1600□ and the second hole transportation layer NPD is coated with a thickness of 150 □.

Vacuum coating with fluorescent blue dopant Ir(pFCNp)3 is applied for the host AND (9,10-di(2-naphthyl)anthracene), forming the first light emission layer with thickness of 250□. At this time, doping density of the fluorescent blue dopant was 5%. The first electron transportation layer Alq3 is coated with a thickness of 200□; N-type charge generation layer Li is coated with a thickness of 100□; and P-type charge generation layer Al is coated with a thickness of 150□.

Next, the third and the fourth hoe transport layer NPD are coated with thickness of 400 and 150□, respectively. Vacuum coating with blue fluorescent dopant Ir(pFCNp)3, green phosphorous dopant Ir(ppy)3, and red phosphorous dopant Ir(mnapy)3 is applied for the host CBP, forming the red light emission layer with a thickness of 250□. At this time, the doping density of the dopant was 2 wt % for each dopant. Next, the second electron transportation layer Alq3 is coated with a thickness of 350□; the electron injection layer LiF is coated with a thickness of 10□; and the cathode Al is coated with a thickness of 1000□, manufacturing an organic light emitting device.

### Comparative Example 1

An organic light emitting device was manufactured under the same process conditions as the experimental example except that the second light emission layer is not doped with the blue fluorescent dopant.

### Comparative Example 2

An organic light emitting device was manufactured under the same process conditions as the experimental example above except that the second light emission layer was formed by doping the host CBP with yellow phosphorous dopant Irpq2acac.

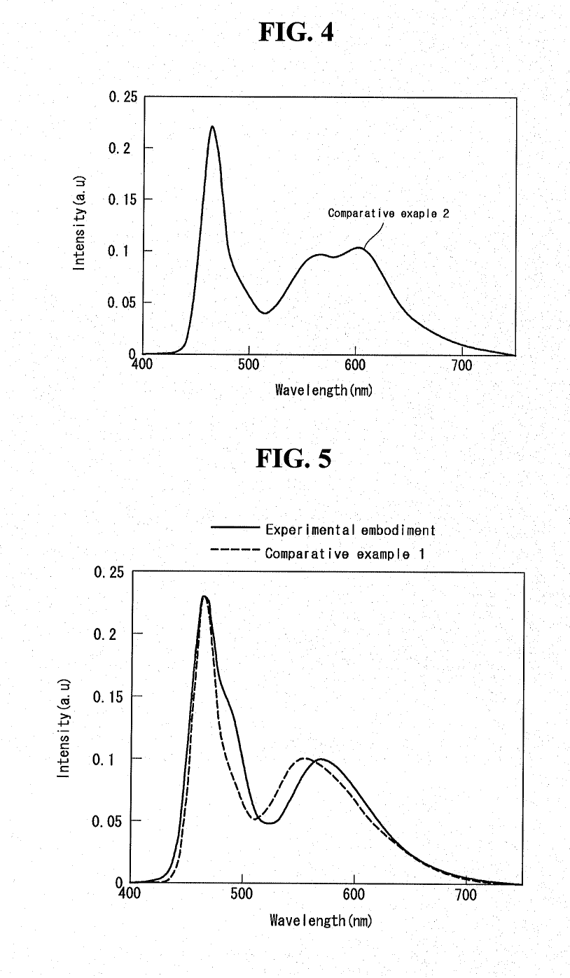

Light emission spectrum of an organic light emitting device manufactured according to the comparative example 2 was measured and the measured result is shown in FIG. 4. Light emission spectrum of an organic light emitting device manufactured according to the experimental example and the comparative example 1 was measured and the measured result is shown in FIG. 5.

With reference to FIGS. 4 and 5, intensity graph along bandwidth ranging from 450 to 500 nm of an organic light emitting device according to the experimental example is wider than those of the comparative example 1 and 2. Accordingly, it can be known that luminous efficiency of blue rays of an organic light emitting device according to the experimental example is improved.

And color filters were installed at the respective organic light emitting devices manufactured according to the experimental example and the comparative example 1. Luminous efficiency and color coordinates were measured and the measurement results are shown in Table 1 below.

TABLE 1

| | | Comparative example 1 | | | | Experimental example | | | |
|---|---|---|---|---|---|---|---|---|---|
| | | Color | | | | | | | |
| | | R | G | B | W | R | G | B | W |
| Color | CIE_x | 0.674 | 0.261 | 0.133 | 0.340 | 0.669 | 0.241 | 0.130 | 0.290 |
| coordinate | CIE_y | 0.324 | 0.657 | 0.062 | 0.333 | 0.326 | 0.637 | 0.068 | 0.604 |
| Efficiency | | 7.85 | 17.35 | 2.705 | 61.26 | 5.234 | 16.69 | 3.723 | 57 |
| (cd/A) | | | | | | | | | |

With reference to Table 1 above, it can be seen that R, G, B color coordinates of the organic light emitting device according to the experimental example have been improved compared with those of the comparative example 1 and luminous efficiency of blue (B) rays has been improved.

Also, white organic light emitting devices were manufactured by installing color filters at the respective organic light emitting devices manufactured according to the comparative example 1 and the experimental example. Power consumption required for while light emission, panel brightness, and panel current were measured and are shown in Tables 2 and 3 below.

TABLE 2
Comparative example 1

| 22 V | R | G | B | W | total |
|---|---|---|---|---|---|
| Power (W) | — | — | — | 129.4 | |
| Panel | 2.3 | 15.0 | 3.1 | 39.4 | 59.9 |
| brightness | | | | | |
| (cd/m²) | | | | | |
| Panel | 0.577 | 1.718 | 2.310 | 1.278 | 1.471 |
| current (A) | | | | | |

TABLE 3
Experimental example

| 22 V | R | G | B | W | total |
|---|---|---|---|---|---|
| Power (W) | — | — | — | 129.4 | |
| Panel | 4.1 | 8.6 | 1.7 | 45.6 | 60.0 |
| brightness | | | | | |
| (cd/m²) | | | | | |
| Panel | 1.541 | 1.024 | 0.891 | 1.589 | 1.261 |
| current (A) | | | | | |

With reference to Tables 2 and 3, it can be seen that a white organic light emitting device manufactured according to the experimental example provides improved power consumption and panel brightness of white rays that those of comparative example 1.

As described above, an organic light emitting device according to one embodiment of the present invention, by forming a first stack comprising a first light emission layer composed of blur phosphorous dopants; and a second stack comprising a third light emission layer formed as a second light emission layer composed of yellow phosphorous dopants or a mix of green and red phosphorous dopants further comprises blue phosphorous dopants, improves color stability and luminous efficiency of the white organic light emitting device and reduces power consumption.

Also, the organic light emitting device according to one embodiment of the present invention can provide an organic light emitting device capable of showing the maximum luminous efficiency by optimizing positions of light emission layers.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112 (6).

What is claimed is:

1. An organic light emitting device, comprising:
an anode;
a first stack disposed on the anode and incorporating a first light emission layer comprising blue dopants for one host;
a charge generation layer disposed on the first stack;
a second stack disposed on the charge generation layer and incorporating blue and yellow dopants for one host or blue, red, and green dopants for one host; and
a cathode disposed on the second stack.

2. The organic light emitting device of claim 1, wherein the first stack comprises a hoe injection layer formed between the anode and the first light emission layer; and comprising
a first hole transportation layer and a second hole transportation layer; and
a first electron transportation layer formed between the first light emission layer and the charge generation layer.

3. The organic light emitting device of claim of claim 1, wherein the second stack further comprising a third hole transportation layer and a fourth hole transportation layer formed between the charge generation layer and the second light emission layer; and
a second electron transportation layer and an electron injection layer formed between the second light emission layer and the cathode.

4. The organic light emitting device of claim of claim 1, wherein the charge generation layer comprises a PN junction charge generation layer.

5. The organic light emitting device of claim of claim 1, wherein blue dopants of the first light emission layer is fluorescent.

6. The organic light emitting device of claim of claim 1, wherein at least one or more of yellow, green, and red dopants of the second light emission layer is phosphorous.

7. The organic light emitting device of claim of claim 1, wherein the blue dopant of the first light emission layer and the second light emission layer is one of a sky blue dopant or a deep blue dopant.

8. The organic light emitting device of claim of claim 1, wherein the first light emission layer is disposed within a range of about 50 to about 75 nm from a surface of the anode.

9. The organic light emitting device of claim of claim 1, wherein the first light emission layer is disposed within a range of about 175 to about 200 mm from a surface of the anode.

10. The organic light emitting device of claim 1, wherein the second light emission layer is disposed within a range of about 285 to about 310 nm from a surface of the first electrode.
